(19) United States
(12) Patent Application Publication
(10) Pub. No.: US 2008/0192811 A1
(43) Pub. Date: Aug. 14, 2008

(54) BEAMFORMING METHODS AND APPARATUS

(75) Inventor: Jae Son, Irving, TX (US)

Correspondence Address: FOLEY & LARDNER LLP, P.O. BOX 80278, SAN DIEGO, CA, 92138-0278, US

(73) Assignee: Nokia Corporation

(21) Appl. No.: 11/673,481

(22) Filed: Feb. 9, 2007

(51) Int. Cl. H04L 5/16; H03K 7/06; H03K 9/06

(52) U.S. Cl. 375/219; 375/302; 375/322; 375/E07.001

(57) ABSTRACT

A method of beamforming comprising: transmitting a plurality of signals from a transmitter, each signal being transmitted over a plurality of subcarriers, each subcarrier having a weight factor associated therewith; receiving the plurality of signals at a receiver; and for each signal: analyzing the received signal in order to obtain its phase profile, the phase profile comprising the phase for each subcarrier; calculating a plurality of parameters representing the phase profile, the plurality of parameters being less in number than the number of subcarriers; sending the plurality of parameters back to the transmitter; reconstructing a representation of the phase profile at the transmitter using the plurality of parameters; and adjusting the weight factor of each subcarrier using the reconstructed representation of the phase profile, wherein further signals are transmitted by the transmitter using the adjusted weight factors.

### FIELD OF INVENTION

The present invention relates to beamforming methods and apparatus for carrying out the same. In particular, embodiments of the present invention relate to multiple-input-single-output beamforming and the application thereof. Certain embodiments relate to user terminals, network entities, and communication systems utilizing the beamforming methods discussed herein.

### BACKGROUND

Multiple-input-single-output beamforming, also known as transmit beamforming or single-receive antenna beamforming, is a well-established closed loop technique used to enhance received signal quality. The technique adjusts the weight of each transmitter antenna so that each transmitted signal can be coherently steered to the receiver yielding both transmitter array gain and diversity gain. See, for example, D. H. Johnson and D. E. Dudgeon, Array Signal Porcessing, New Jersey: Printice Hall, 1993. Indeed, the term “beamforming” has traditionally often been used to describe multiple transmit antenna beam steering to a single receive antenna to increase the received signal-to-noise ratio (SNR) or to reject any unwanted interference signals.

Recently, the definition of the term “beamforming” has been extended to include multiple transmit and receive antenna systems, known as multiple-input-multiple-output systems, with various multi-spatial streams.

Known beamforming techniques include eigen beamforming (EBF), a transmit power control algorithm, and a precoding scheme based on a unitary space-time constellation design. Eigen beam forming has been shown to yield optimal performance in relation to increases in the signal-to-noise ratio and capacity improvement when implemented along with an appropriate bit-loading scheme.

Despite the above, single-receive antenna beamforming applications are still extensively investigated by both academia and industry since, for example, the majority of mobile terminals in a mobile communication system have a single antenna due to cost, size, and power consumption considerations.

As previously indicated, there have been numerous research investigations on beamforming techniques. Eigen beam forming and transmitter power control methods are a well known implementation. See, for example, Farrokh Rashid-Farrokhi, K. J. Ray Liu, and Leandros Tassiulas, “Transmit Beamforming and Power Control for Cellular Wireless Systems”, IEEE JSAC, vol. 16, no. 8, October 1998, pp. 1437-1450 and Vincent Lau, Youjian Liu and Tai-Ann Chen, “On the Design of MIMO Block-Fading Channels With Feedback-Link Capacity Constraint”, IEEE Trans. Comm., vol. 52, no. 1, January 2004, pp. 62-70.

However, recently, a great deal of beamforming research activities has been focused on precoding approaches since the precoding approach seems to accommodate beamforming techniques much better under a limited feedback environment. See, for example, David J. Love and Robert W. Heath Jr., “Limited Feedback Precoding for Spatial Multiplexing Systems”, Proc. IEEE GLOBECOM, vol. 4, December 2003, pp. 1857-1861.

A unitary constellation design by Hochwald is widely used as a precoding matrix as set out in Bertrand M. Hochwald, Thomas L Marzetta, and Thomas J. Richardson, Wim Sweldens, Rudiger Urbanke, “Systematic Design of Unitary Space-Time Constellations”, IEEE Trans. Information Theory, vol. 46, no. 6, September 2000, pp. 1962-1973.

A linear constellation precoding method has been proposed for OFDM systems to maximize the diversity gain and coding gain as set out in Zhiqiang Liu, Yan Xin, and Georgios B. Giannakis, “Linear Constellation Precoding for OFDM with Maximum Multipath Diversity and Coding Gains”, IEEE Trans. Comm., vol. 51, no. 3, March 2003, pp. 416-427.

A channel covariance feedback scheme has been proposed as an alternative beamforming solution under a limited feedback environment. See, for example, Syed Ali Jafar, Sriram Vishwanath, and Andrea Goldsmith, “Channel Capacity and Beamforming for Multiple Transmit and Receive Antennas with Covariance Feedback”, Proc. IEEE ICC, vol. 7, June 2001, pp. 2266-2270 and Steven H. Simon and Aris L. Moustakas, “Optimizing MIMO Antenna Systems With Channel Covariance Feedback”, IEEE JSAC, vol. 21, no. 3, April 2003, pp. 406-417.

A combined approach of beamforming and space time coding has also been proposed in G. Jorgren, M. Skoglund, B Ottersten, “Combining Beamforming and Orthogonal Space-Time Block Coding”, IEEE Trans. Information Theory, vol. 48, no. 3, March 2002, pp. 611-627.

As mentioned above, transmit beamforming steers each transmitter antenna signal (which is equivalent to multiplying a complex weight to each antenna signal) such that the received signal at the receiver can be coherently combined to yield transmitter array gain and diversity gain or to reject unwarranted interfering signals. Such beamforming presumes the full knowledge of the link condition (or channels) available at the transmitter. However, one major practical issue is that in reality only limited feedback information is available at the transmitter. Thus, it is necessary to find some innovative beamforming approach that requires limited feedback information to the transmitter but simultaneously incurs no significant performance degradation.

For systems which utilize orthogonal frequency-division multiplexing (OFDM), known transmit beamforming schemes resemble some form of parallel implementation of existing narrow bandwidth beamforming methods performed in the frequency domain. However, conventional beamforming methods require accurate feedback information from the receiver to the transmitter. Furthermore, in practice, the feedback bandwidth is usually very limited. The present inventors have thus realized that a brute force parallel implementation of conventional beamforming techniques is not an attractive solution for beamforming in an OFDM system. Even if sub-channel correlation of an OFDM system can be exploited to reduce the number of parallel implementations, further improvements are necessary in order to reduce the amount of feedback information to the transmitter while simultaneously incurring no significant performance degradation, particularly for severe frequency selective channels. Accordingly, OFDM beamforming in a limited information feedback environment is a challenging problem to solve.

In light of the above, there are two major beamforming issues to be addressed for implementation in an OFDM system. The first issue is how much feedback information should be delivered from the receiver to the transmitter since in reality only a limited amount of feedback information can be transmitted back to the transmitter given the limited bandwidth available for feedback of this information in an OFDM system. The second issue is how to implement a narrow bandwidth beamforming method for the OFDM system while avoiding mere parallel implementation in each sub-channel.

It is therefore an aim of certain embodiments of the present invention to solve one or more of the problems outlined above. That is, it is an aim of certain embodiments of the present invention to devise an effective multiple-input-single-output beamforming method for an OFDM system which requires limited feedback bandwidth from a receiver (e.g. a user terminal) to a transmitter (e.g. a base station). It is a further aim of certain embodiments of the present invention to provide user terminals, network entities, and communication systems which utilizing the aforementioned beamforming method.

### SUMMARY

According to an embodiment of the present invention there is provided a method comprising receiving a plurality of signals over a plurality of subcarriers, each subcarrier having a weight factor associated therewith and analyzing the received signals in order to obtain a phase profile comprising phases of the subcarriers. A plurality of parameters is then calculated, the parameters representing the phase profile. The plurality of parameters is less in number than the number of subcarriers. The plurality of parameters is then sent to a transmitter for use in reconstruction of a representation of the phase profile.

According to another embodiment there is provided a method comprising transmitting a plurality of signals over a plurality of subcarriers, each subcarrier having a weight factor associated therewith and receiving a plurality of parameters from a receiver of the plurality of signals, the plurality of parameters representing a phase profile and being less in number than the number of subcarriers. A representation of the phase profile is then reconstructed using the plurality of parameters and the weight factor of each subcarrier is adjusted using the reconstructed representation of the phase profile. Further signals can then be transmitted using the adjusted weight factors.

A transmitter, a receiver and a communications system wherein the methods are implemented may also be provided.

The inventors have realized that it is not necessary to feedback parameters representing the phase of each subcarrier of a signal. Instead, parameters representing the phase profile of the received signal can be calculated at the receiver and these parameters can then be sent back to the transmitter for beamforming. Calculation of parameters representing the phase profile can be be such that the number of parameters is less than the number of subcarriers in order to achieve a bandwidth saving when compared to prior art arrangements in which carriers representing the phase of each subcarrier of a signal are sent back to the transmitter for beam forming.

According to one arrangement, the calculating step comprises performing a linear least squares fit of the phase profile to obtain a first parameter representing an initial bias and a second parameter representing the slope of the linear least squares fit, the sending step comprises sending the first and second parameters back to the transmitter, and the reconstructing step comprises reconstructing the linear least squares fit representing the phase profile, the reconstructed least squares fit being used to adjust the weight factor of each subcarrier in the adjusting step.

It has been found that in many arrangements, the phase profile of each received signal is approximately linear across the subcarriers. Accordingly, a linear least squares fit can be used to approximate the phase profile. The linear least squares fit can be defined using only two parameters, the initial bias and the slope of the line. These two parameters can be sent back to the transmitter which can then use the parameters to reconstruct the linear least squares fit representing the phase profile and use the reconstructed linear least squares fit for beamforming.

According to another arrangement, the calculating step comprises calculating a phase difference for each subcarrier relative to a reference signal and the sending step comprises sending parameters representing the phase differences back to the transmitter.

By using one of the signals as a reference signal and calculating phase difference for the other received signals, the number of parameters is reduced. For example, for a two signal system, the difference values define the relative phase of both signals rather than requiring a set of parameters for each signal.

According to yet another arrangement, a hybrid of the previously described arrangements can be provided wherein the calculating step comprises performing a linear least squares fit of the phase differences to obtain a first parameter representing an initial bias and a second parameter representing the slope of the linear least squares fit, the sending step comprises sending the first and second parameters back to the transmitter, and the reconstructing step comprises reconstructing the linear least squares fit representing the phase differences, the reconstructed least squares fit being used to adjust the weight factor of each subcarrier in the adjusting step.

This arrangement reduces the number of parameters yet further. In a two signal system, the two parameters representing the least squares fit can be used to define the relative phase of both signals. As such the number of parameters is reduced when compared with the previously described least squares fit arrangement which requires two parameters per signal. Furthermore, the number of parameters is reduced when compared with the previously described phase differential arrangement which requires a set of phase difference values for the two signals.

The plurality of parameters representing the phase profile may comprise actual values representing the phase profile and each parameter may be quantized into a number of bits. Alternatively, a look-up table may be used to generate indices matching the phase for each subcarrier with a closest value in the look-up table. The indices can then be sent back to the transmitter, and another look-up table can be used to reconstructs a representation of the phase profile at the transmitter using the indices.

Sending indices rather than actual values can further reduce the bandwidth required for the feedback mechanism.

The previously described approximations of the phase profile may deviate somewhat from the actual phase profile. Accordingly, one or more phase error corrections may be applied such that the approximation of the phase profile more closely represents the actual phase profile of a received signal. A filter may also be used at the receiver to yield a more linear phase profile.

The transmitter may comprise a plurality of antennas, each antenna transmitting a signal over a plurality of subcarriers. Furthermore, the plurality of signals may be received at a single receiver. When multiple transmit antennas and a single receiver antenna is used, the system is known as a multiple-input-single output (MISO) beamforming.

Such a transmitter may be provided in a network entity of a telecommunications network such as a base station.

### BRIEF DESCRIPTION OF THE FIGURES

For a better understanding of the embodiments and how the same may be carried into effect, reference will now be made by way of example only to the accompanying drawings in which:

FIG. 1 illustrates the main elements of an exemplifying mobile communication network in which embodiments of the present invention can be implemented;

FIG. 2 shows a schematic illustration of a multiple-input-single-output OFDM beamforming system;

FIG. 3 shows three graphs illustrating: (a) filter frequency response; (b) filter phase response; and (c) channel phase of an 802.11n Channel B along with a linear least square fit line (52 used sub-carriers).

FIG. 4 shows a schematic illustration of an M×1 multiple-input-single-output OFDM linear least square fit beamforming system according to an embodiment of the present invention;

FIG. 5 shows a schematic illustration of 2×1 differential channel phase beamforming according to an embodiment of the present invention;

FIG. 6 shows a schematic illustration of an M×1 multiple-input-single-output OFDM differential channel phase beamforming according to an embodiment of the present invention;

FIG. 7 shows a schematic illustration of an M×1 multiple-input-single-output OFDM differential channel phase—linear least square fit hybrid beamforming arrangement according to an embodiment of the present invention;

FIG. 8 is a graph illustrating raw bit-error-ratio performance curves of OFDM transmit beamforming methods under 802.11n Channel B;

FIG. 9 is a graph illustrating raw bit-error-ratio performance curves of 2×1 OFDM linear least square fit beamforming methods under 802.11n Channel B;

FIG. 10 is a graph illustrating raw bit-error-ratio performance curves of 2×1 OFDM linear least square fit beamforming methods under 802.11n Channel D; and

FIG. 11 is a graph illustrating raw bit-error-ratio performance curves of multiple-input-single-output OFDM differential channel phase—linear least square fit hybrid beamforming methods under 802.11n Channel B.

### DETAILED DESCRIPTION OF EMBODIMENTS

It will be understood that in the following description embodiments of the present invention are described with reference to particular non-limiting examples from which the invention can be best understood. The invention, however, is not limited to such examples.

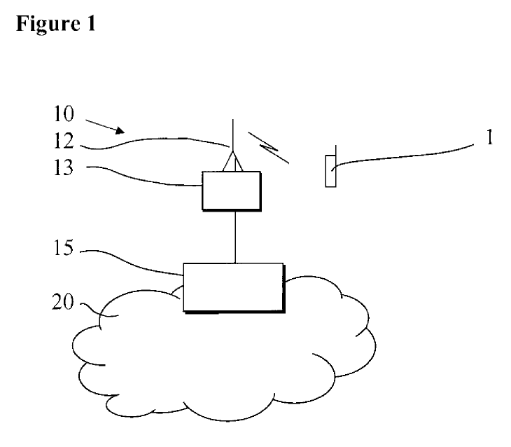

FIG. 1 shows a non-limiting example of mobile architecture in which embodiments of the present invention can be implemented. The illustrated system is known as Evolved Universal Terrestrial Radio Access (E-UTRA). An exemplifying implementation is therefore now described in the framework of an Evolved Universal Mobile Telecommunication System (UMTS) Terrestrial Radio Access Network (E-UTRAN).

An Evolved Universal Terrestrial Radio Access Network (E-UTRAN) consists of E-UTRAN Node Bs (eNBs) which are configured to provide both base station and control functionalities of the radio access network. The eNBs may provide E-UTRA features such as user plane radio link control/medium access control/physical layer protocol (RLC/MAC/PHY) and control plane radio resource control (RRC) protocol terminations towards the mobile devices. It is noted, however, that the E-UTRAN is only given as an example and that the invention can be embodied in any access system or combination of access systems.

A communication device can be used for accessing various services and/or applications provided via a communication system as shown in FIG. 1. In wireless or mobile systems the access is provided via an access interface between a mobile communication device 1 and an appropriate wireless access system 10. A mobile device 1 can typically access a communication system wirelessly via at least one base station 12 or similar wireless transmitter and/or receiver node. Non-limiting examples of appropriate access nodes are a base station of a cellular system and a base station of a wireless local area network (WLAN). Each mobile device may have one or more radio channels open at the same time and may receive signals from more than one base station.

A base station is typically controlled by at least one appropriate controller entity 13 so as to enable operation thereof and management of mobile devices in communication with the base station. The controller entity is typically provided with memory capacity and at least one data processor. In FIG. 1 the base station node 12 is connected to a data network 20 via an appropriate gateway 15. A gateway function between the access system and another network such as a packet data network may be provided by means of any appropriate gateway node, for example a packet data gateway and/or an access gateway.

Certain embodiments of the present invention may be implemented in the above-described system architecture in order to improve signalling between the base station 12 and the mobile device 1. The base station 12 may comprise a plurality of transmitters in an array which can be used to send a plurality of signals on a channel to the mobile device 1 which has only a single receiver for receiving the plurality of signals. The mobile device 1 sends feedback information about the channel to the transmitter array of the base station which is used to control the signals transmitted by the array such that the received signals at the mobile device can be coherently combined to yield transmitter array gain and diversity gain or to reject unwarranted interfering signals. Examples of how this process is implemented are set out below.

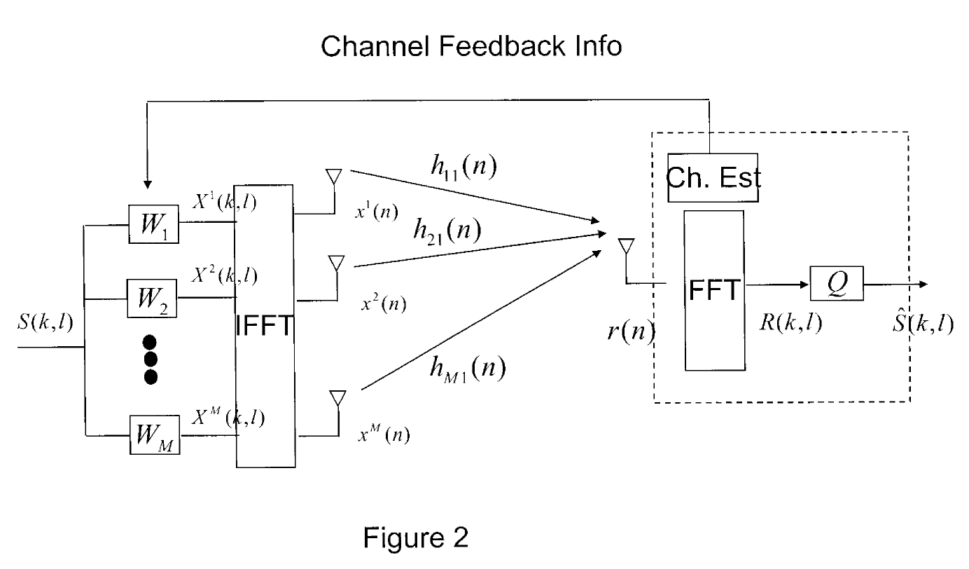

FIG. 2 shows a schematic overview of a multiple-input-single-output orthogonal frequency division multiplexing beamforming system (a MISO OFDM BF system for short) implemented in the frequency domain (per subcarrier basis). S(k, l) represents a modulation symbol at kth subcarrier in lth OFDM symbol. A beamforming (BF) weight, Wₘ(k, l), of mth transmitter antenna is weighted to the modulation symbol to yield a BF symbol

X^{m}(k,l)=Wₘ(k,l)S(k,l). (1)

Since only one receive antenna is considered here, one data stream will be assumed. Also, it is assumed that the BF algorithm is applied within the channel coherence time, which usually spans multiple OFDM symbol periods or the burst packet duration. Therefore, the OFDM symbol index l has been dropped throughout the remainder of this discussion assuming that the BF operation is conducted during the channel coherence time. The weighted modulation symbol, X^{m}(k, n), is collected per antenna basis for an Inverse Fast Fourier Transform (IFFT) operation yielding the time domain signal, x^{m}(n)

$${x}^{m} ( n ) = {\sum }_{k = 1}^{N} {X}^{m} ( k ) {e}^{\frac{j2 π nk}{N}} . \qquad ( 2 )$$

N represents the IFFT size. The receiver signal is obtained by the convolution operation between the time domain signal and the channel impulse response plus some additive white gaussian noise (AWGN) signal as follows

$$r ( n ) = {\sum }_{m = 1}^{M} {x}^{m} ( n ) * {h}_{m} ( n ) + w ( n ) \qquad ( 3 )$$

Under the perfect synchronization and channel state information (CSI) assumption at the receiver, the frequency domain receiver signal, R(k), is obtained after the Fast Fourier Transform (FFT) operation of r(n). Then, depending on the BF scheme implemented, R(k) can be further weighted by Q(k) to yield an estimated symbol

Ŝ(k)=Q(k)R(k). (4)

The main feature of a traditional BF system is to determine the weights Wₘ(k) and R(k) (if necessary) in order to maximize transmit diversity and array gain or to minimize interference signal power at the receiver.

Certain proposed BF schemes in this specification are designed for maximizing the diversity and array gain of an OFDM system under limited feedback bandwidth based on the exploitation of channel phase characteristics. Some examples of the newly proposed BF algorithms are discussed in more detail below. Note that throughout this specification, perfect synchronization and perfect channel state information at the receiver is assumed. However, channel feedback information is obtained from a simple channel estimation under the assumption that the channel length is less than the channel coherence (CP) length. Furthermore, no feedback error is assumed from the receiver to the transmitter.

Let us assume that a transmitter is a base station and a receiver is a user mobile terminal. One conventional narrow bandwidth transmit BF algorithm is shown below where transmitter BF weights steer the transmitted signal to cancel out phase rotation caused by the channel:

$${W}_{m} ( k ) = - ∠ {H}_{m} ( k ) \\ where \\ {H}_{m} ( k ) = {\sum }_{n = 0}^{{N}_{n} - 1} {h}_{m} ( n ) {e}^{- \frac{j2 π nk}{N}} . \qquad ( 5 )$$

This channel phase BF requires no additional operation at the receiver, thus Q(k)=1. Note that this narrow bandwidth BF algorithm can be implemented for the OFDM system in the frequency domain per subcarrier basis. The channel information, which is, for this example,

∠Hₘ(k)

has to be available at the transmitter. This channel information can be obtained either by a channel estimation operation from uplink preambles (under the assumption of channel reciprocity) or a channel feedback operation from the receiver. The former approach is less common since most downlink and uplink frequency spectrums are different. For the later approach, it is assumed that there exists sufficient feedback bandwidth (FBW) to accurately deliver channel feedback information. However, in practice, most wireless systems consider only a limited FBW such that often full precision channel information won't be available at the transmitter. Consequently, feedback information has to be delivered as a quantized value or an index of a pre-determined look-up table known both to the transmitter and the receiver. One major motivation for newly proposed BF algorithms is to find an effective MISO OFDM BF solution to conduct the BF operation in a limited FBW environment without sustaining significant performance loss. It is shown below that this objective can be achieved by exploiting the phase characteristics of the channel frequency response,

∠Hₘ(k)

known as “channel phase” in the frequency domain.

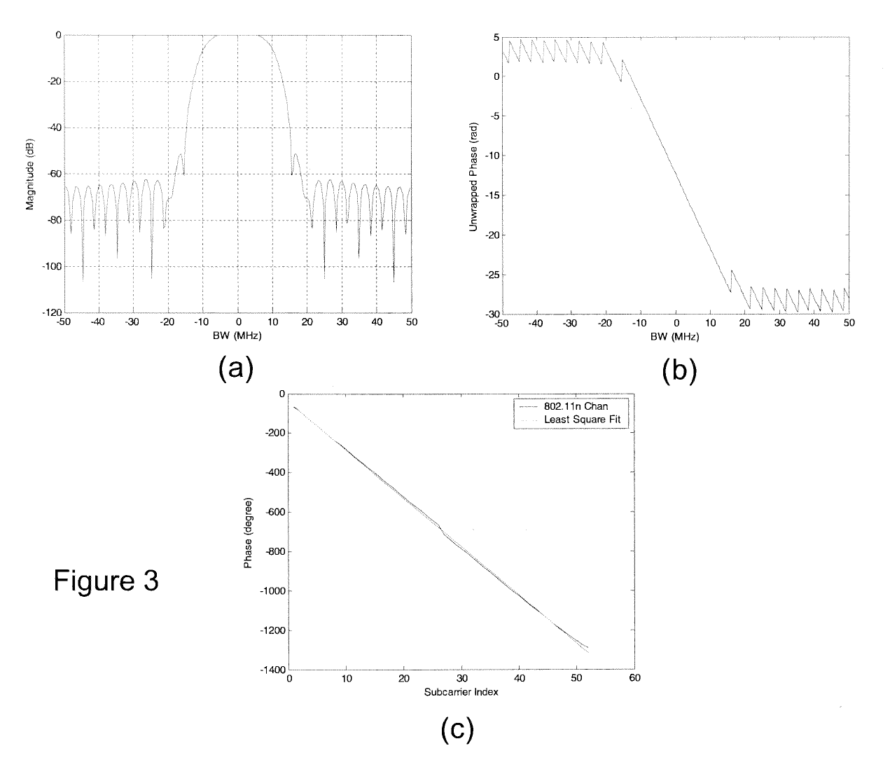

FIG. 3(c) shows an example of the overall channel phase (802.11n Channel Model B) observed at the receiver. Interestingly, the received channel phase shows a linear phase characteristic. The question arises, however, how a wireless channel can exhibit a linear phase characteristic unless the channel impulse response, h(n), has either a symmetric or anti-symmetric shape. This linear phase characteristic is the by-product of the digital low pass filter implemented in the receiver for the sample decimation operation where its filter characteristics are shown in the FIGS. 3(a) and (b).

In general, most receivers contain some type of an analogue or digital filter for signal extraction and recovery. For example, Analog-to-Digital Converter (ADC) has a built-in low pass filter to prevent anti-aliasing. Usually the filter is designed such that the passband region will yield a linear phase characteristic in order to induce a constant filter delay on the filtered signal. This observation can be exploited to render an effective solution for the OFDM BF system. As shown in the FIG. 3(c), the unwrapped channel phase can be represented by an approximate linear function, Linear Least Square Fit (LLSF). The LLSF parameters can be found from the well-known set of equations in J. G. Proakis and D. G. Manolakis, Digital Signal Processing, New Jersey: Printice Hall, 1996:

$$y = ax + b \\ a = \frac{N \sum xy - \sum x \sum y}{N \sum {x}^{2} - {( \sum x )}^{2}} \\ b = \frac{\sum y \sum {x}^{2} - \sum x \sum xy}{N \sum {x}^{2} - {( \sum x )}^{2}} \qquad ( 6 )$$

With the following substitutions

x=1, 2, . . . Nᵤ

y=φₘ₁(x)=∠Hₘ(k)

N=Nᵤ (7)

LLSF parameters can be found accordingly

φₘ₁(k)=aₘ·k+bₘ m=1, 2, . . . M (8)

This suggests that now LLSF parameters alone can represent the whole channel phase profile, and they can be sent back as feedback information. However, there would still be phase errors,

Δφₘ₁^{lsf}(k)

associated with this linear least square fitting approximation

Δφₘ₁^{lsf}(k)=φₘ₁(k)−aₘk−bₘ k=1, 2, . . . Nᵤ (9)

Also, this phase error is observed when Inter-Symbol Interference (ISI) exists due to a long channel length. Thus, to reduce the performance degradation caused by non-linear channel phase characteristics, these phase errors can be sent along with the LLSF parameters. Instead of sending actual parameter values and phase errors, the index of phase tables can be sent back to the transmitter in order to further lower the amount of feedback information

Q[aₘ],Q[bₘ],Q[Δφₘ₁^{lsf}(k)] m=1, 2, . . . M k=1, 2, . . . Nᵤ (10)

where Q[·] represents a look-up table function that generates the index that matches to the closest value in the look-up table. To illustrate how much feedback information is required, the following example of a simple quantization bit calculation will be provided.

As mentioned earlier, if a brute force parallel implementation across all subcarriers is sought for the OFDM implementation from the narrow bandwidth BF algorithm (5), this approach requires sending Nᵤ·M pieces of feedback phase information per transmission where Nᵤ is the number of occupied subcarriers (data plus pilots) within one OFDM symbol. Furthermore, if each phase is quantized to L bits, then the total number of feedback bits required for the narrow bandwidth BF scheme (5) is Nᵤ·M·L bits for an M×1 MISO OFDM system.

In contrast, the proposed LLSF BF scheme requires two parameters, Q[aₘ] and Q[bₘ], per transmitter antenna if the channel phase characteristic shows a reasonable linear shape as shown in the FIG. 3(c). Consequently, the total number of feedback bits is 2M·L if each parameter is quantized to L bits. The number of feedback bits required can thus be reduced by a factor of

$$\frac{{N}_{u}}{2} \vert$$

The channel phase reconstruction of LLSF BF at the transmitter can be obtained as follows

Wₘ(k)=−φₘ₁(k)=Q[aₘ]·k+Q[bₘ]+Q[Δφₘ₁^{lsf}(k)] k=1, 2, . . . Nᵤ (11)

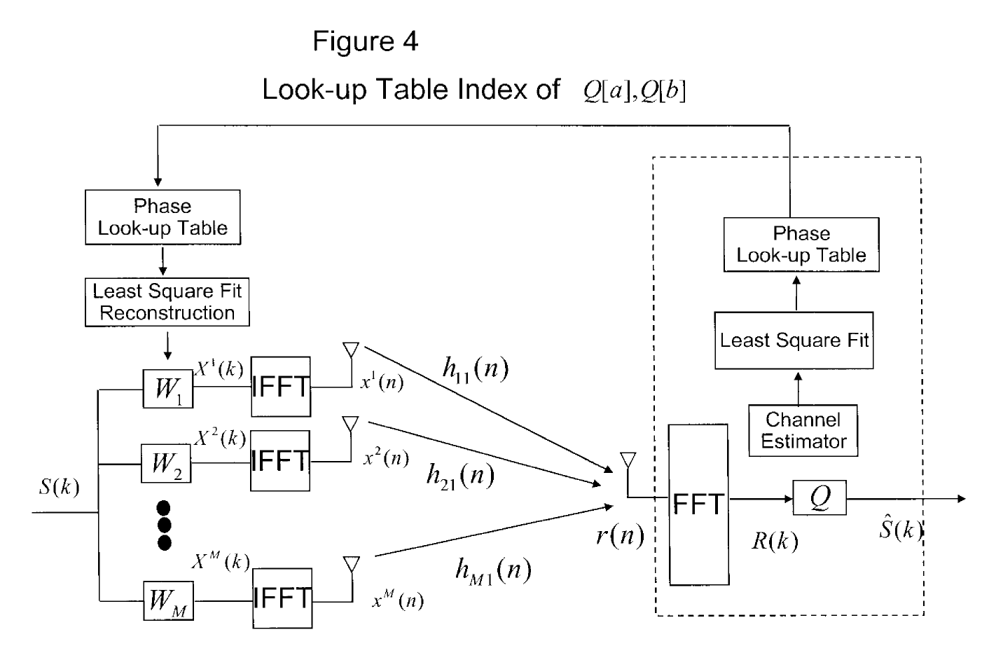

The last phase error term can be added for robust operation when the characteristic of the channel phase exhibit more nonlinearity. An overall block diagram of the proposed LLSF OFDM BF scheme is shown in FIG. 4.

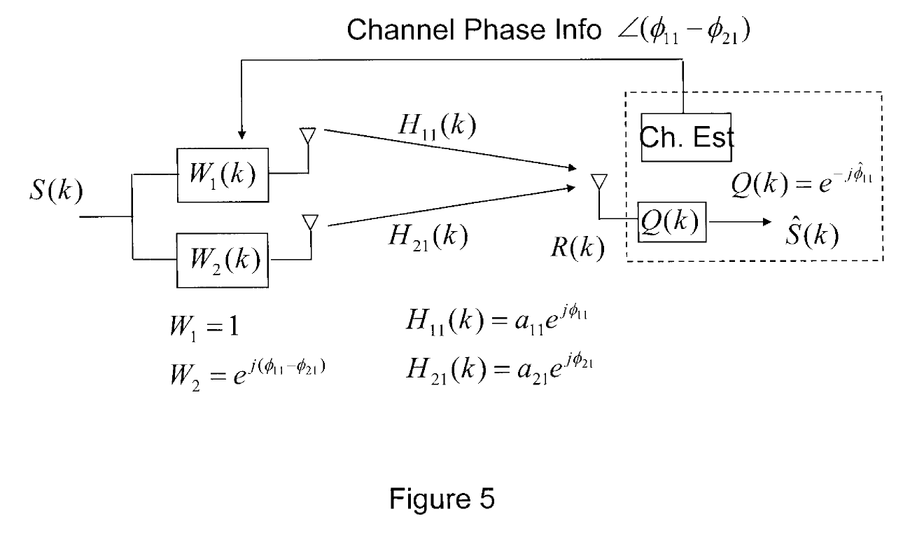

Instead of sending the channel phase information for each transmitter antenna, it is possible to send the difference of channel phases between one reference transmitter and the rest of them and apply the BF weights. An example of a 2×1 differential channel phase (DCP) beamforming arrangement is shown in FIG. 5 for an OFDM frequency domain implementation. By sending channel phase difference information, it is possible to fix the first BF weight to be 1. Accordingly, instead of sending 2 (or M) feedback information, only 1 (or M−1) channel feedback information is required. Since the feedback information now comprises channel phase difference information, rather than channel phase information itself, the phase of a received signal is steered to φ11(k) as shown below

$$\begin{matrix}R ( k ) = {W}_{1} ( k ) \cdot {H}_{11} ( k ) + {W}_{2} ( k ) \cdot {H}_{21} ( k ) \\ = 1 \cdot {a}_{11} ( k ) {e}^{j {φ}_{11} ( k )} + {e}^{j ( {φ}_{11} ( k ) - {φ}_{21} ( k ) )} \cdot {a}_{21} ( k ) {e}^{{jφ}_{21} ( k )} \\ = {a}_{11} ( k ) {e}^{{jφ}_{11} ( k )} + {a}_{21} ( k ) {e}^{{jφ}_{11} ( k )} \\ = ( {a}_{11} ( k ) + {a}_{21} ( k ) ) {e}^{{jφ}_{11} ( k )}\end{matrix} \qquad ( 12 \text{-} 15 )$$

Thus, a phase correction is needed at the receiver for correct symbol detection

Ŝ(k)=R(k)·Q(k)=(a₁₁(k)+a₂₁(k))e^{jφ}^{₁₁}^{(k)}·e^{-jφ}^{₁₁}^{(k)} (16)

where

aₘ₁(k)=|Hₘ₁(k)| and φₘ₁(k)=∠Hₘ₁(k).

The term

\hat{φ}₁₁(k)

represents the channel phase estimated from the latest channel estimation at the receiver, which could be different from the previous phase estimate available at the transmitter. Again, if this BF process is conducted within the channel coherence time, the phase discrepancy should be small to cause negligible performance degradation.

In order to further reduce the feedback information bits, the following scheme is proposed. First, the channel phase difference of the mth transmitter at the kth subcarrier is defined as

Δφₘ)k)=(φ₁₁(k)−φₘ₁(k)) m=2, 3, . . . M (17)

indicating that the first antennas is the reference antenna to obtain the channel phase difference. If channel coherence bandwidth spans several subcarriers, then the phase difference between adjacent subcarriers

∠Θₘ(k)=Δφₘ(k)−Δφₘ(k+1) (18)

shows a limited variation. This limited variation means a limited dynamic range for the quantization operation, thus requiring less quantization bits (less than L bits) for each subcarrier.

Next, instead of sending quantized phase values of

∠Θₘ(k),

a look-up table approach can be used so that the index of the look-up table can be sent instead. The transmitted information from the receiver to the transmitter is

Q[Δφₘ(1)], Q[φΘₘ(k)], m=2, 3, . . . , M k=1, 2, . . . , Nᵤ−1 (19)

For an M×1 MISO system, this scheme requires (M−1)·Nᵤ·J feedback bits where J<<L. The transmitter is able to retrieve the BF weight, Wm(k), from

Q[∠Θₘ(k)] and Q[Δφₘ(1)]

through a reverse operation of the equation (18):

Wₘ(1)=Q[Δφₘ(1)]

Wₘ(k+1)=Q[Δφₘ(k)]−Q[∠Θₘ(k)] (20)

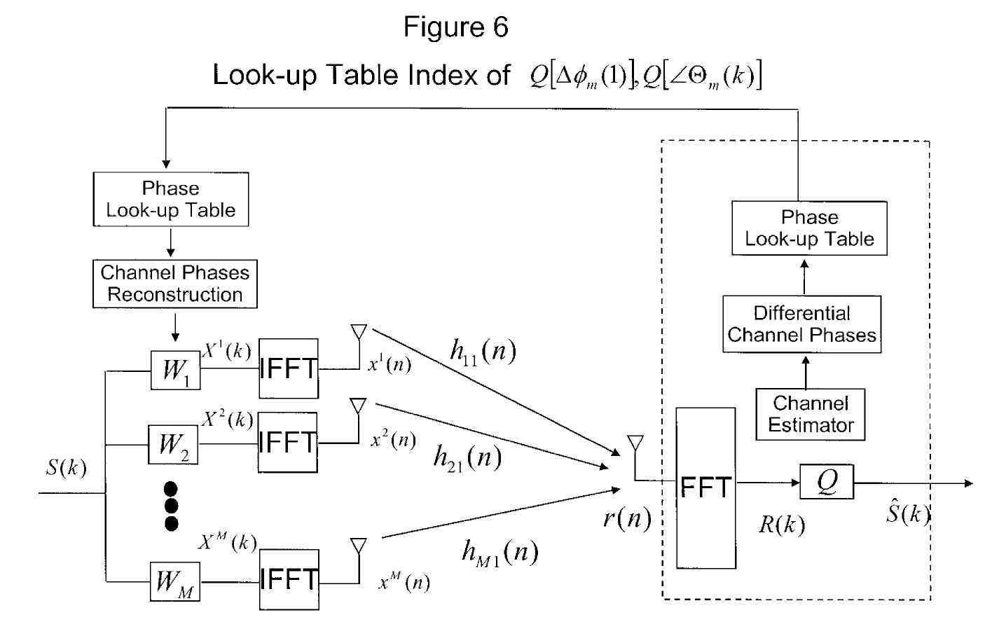

Note that the receiver needs to compensate for the phase rotation of φ11(k). FIG. 6 illustrates an overview of DCP beamforming algorithm.

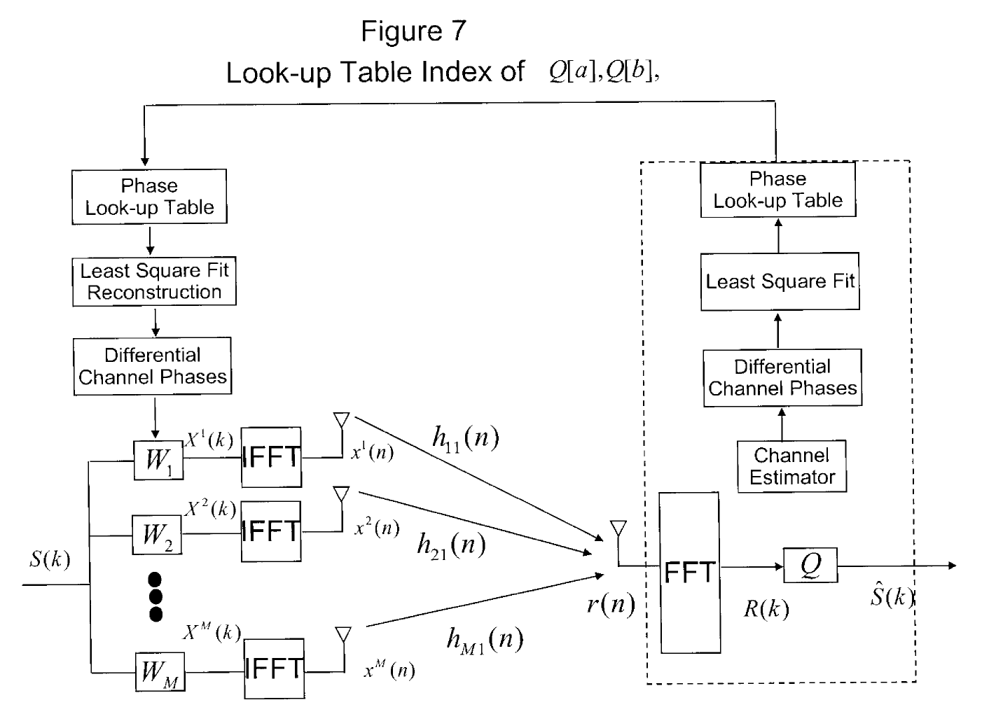

A combined approach using a DCP-LLSF beamforming algorithm is shown in FIG. 7. For this hybrid BF scheme, first a DCP BF is used to render the channel phase difference, Δφₘ(k), among different antennas. Then, a LLSF scheme is applied on Δφₘ(k) to yield aₘ and bₘ. The DCP-LLSF parameters can be obtained from the following substitutions put into the equation (6):

x=k=1, 2, . . . Nᵤ

y=Δφₘ(k) m=2, 3, . . . M

N=Nᵤ (21)

However, it has been observed that the channel phase difference, Δφₘ(k), tends to show more distorted linear phase characteristics such that LLSF error terms are needed along with LLSF parameters

Δφₘ^{lsf}(k)=Δφₘ(k)−aₘk−bₘ k=1, 2, . . . Nᵤ m=2, 3, . . . M

Q[aₘ], Q[bₘ], Q[Δφₘ₁^{lsf}(k)] m=2, 3, . . . M k=1, 2, . . . Nᵤ (22, 23)

Computer simulation has been conducted to verify the concept and performance of the proposed MISO OFDM beamforming schemes, which have been integrated into an 802.11n WLAN simulator. The key simulation parameters are shown in the Table I. Perfect synchronization and perfect channel state information are assumed at the receiver side. However, channel feedback information is obtained by channel estimation performed at the receiver without any AWGN noise addition. At the transmitter side, the feedback information is assumed to be delivered without any error. In addition, it is assumed that beamforming operates within the channel coherence time.

Table II shows quantization parameters for a 2×1 MISO BF computer simulation. The total bits represent the number of quantized bits transmitted from the receiver to the transmitter for a particular beamforming operation. For the example of DCP beamforming, 6 bits are allocated for the first phase value and 5 bits are allocated for the differential phase value. The quantization range of

∠Θₘ(k)

is set between −60 and 60 degrees. For LLSF and DCP-LLSF beamformings, 6 bits are allocated for each parameter of aₘ and bₘ, and only 3 bits are allocated for the phase error information,

Δφₘ₁^{lsf}(k)

when needed. For LLSF beamforming scheme, instead of sending one set of aₘ and bₘ parameters, two sets are sent to compensate for subcarrier discontinuity within the whole occupied subcarriers of the 802.11n channel.

TABLE I
SIMULATION SETTINGS

| | |
|---|---|
| Packet Length | 1000 Bytes |
| FFT Size | 64 |
| Used Subcarriers | 52 |
| Cyclic Prefix | 16 |
| MISO Configuration | 2 × 1, 3 × 1, 4 × 1 |
| Symbol Modulation | 16QAM |
| Carrier Freq | 5.25 GHz |
| Signal BW | 20 MHz |
| Channel | 802.11n Channel Model B and D |

TABLE II
QUANTIZATION SETTINGS FOR 2 × 1 MISO BEAMFORMING SCHEMES

| | Δφₘ(l) | aₘ | bₘ | ∠Θₘ(k) | Δφₘₗ^{lsf}(k) | Phase Range | Total Bits (Packet) |
|---|---|---|---|---|---|---|---|
| 2 × 1 LLSF | na | 6 | 6 | na | na | na | 2 × 4 × 6 = 48 bits |
| 2 × 1 LLSF:Err | na | 6 | 6 | na | 3 | (−30°, 30°) | 2 × (2 × 6 + 52 × 3) = 336 bits |
| 2 × 1 DCP | 6 | na | na | 5 | na | (−60°, 60°) | 6 + 51 × 5 = 261 bits |
| 2 × 1 DCP-LLSF:Err | na | 6 | 6 | na | 3 | (−120°, 120°) | 2 × 6 + 52 × 3 = 168 bits |

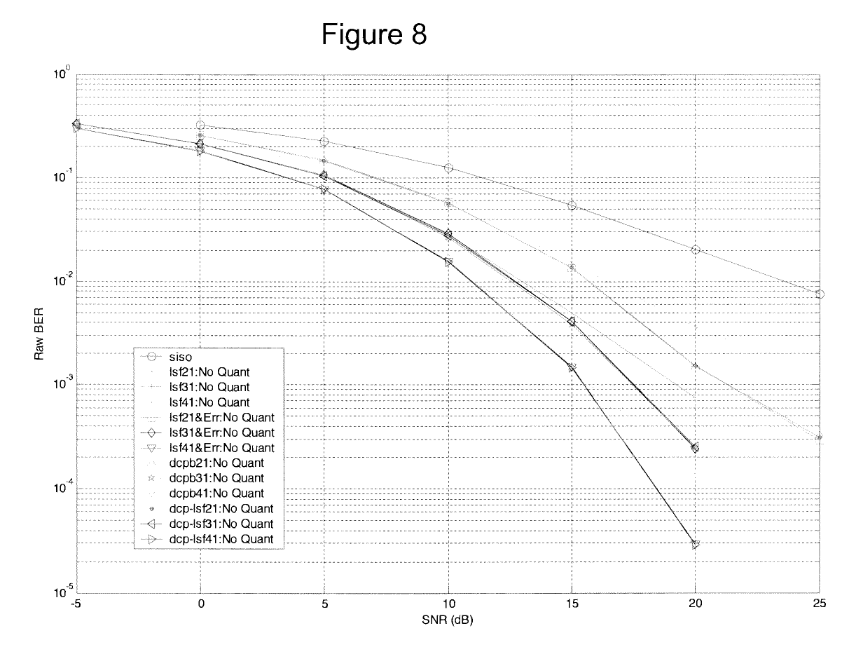

FIG. 8 shows raw BER performance of the MISO OFDM beamforming schemes when no quantization is applied for the feedback information. Results are shown for linear least squares fit beamforming (lsf in FIG. 8), linear least squares fitting and phase error correction beamforming (lsf&Err in FIG. 8), differential channel phase beamforming (dcpb in FIG. 8), and hybrid differential channel phase—linear least squares fit beamforming (dcp-lsf in FIG. 8).

Noticeable performance gains can be observed when compared to a single antenna system (single-input-single-output or SISO). However, LLSF BF seems to lose diversity gain at high SNR compared to other schemes due to residual phase errors uncompensated at the transmitter. As shown, when these phase errors are available at the transmitter, performance is no different from other proposed BF schemes where high transmitter diversity gains seem to be obtained at high SNR.

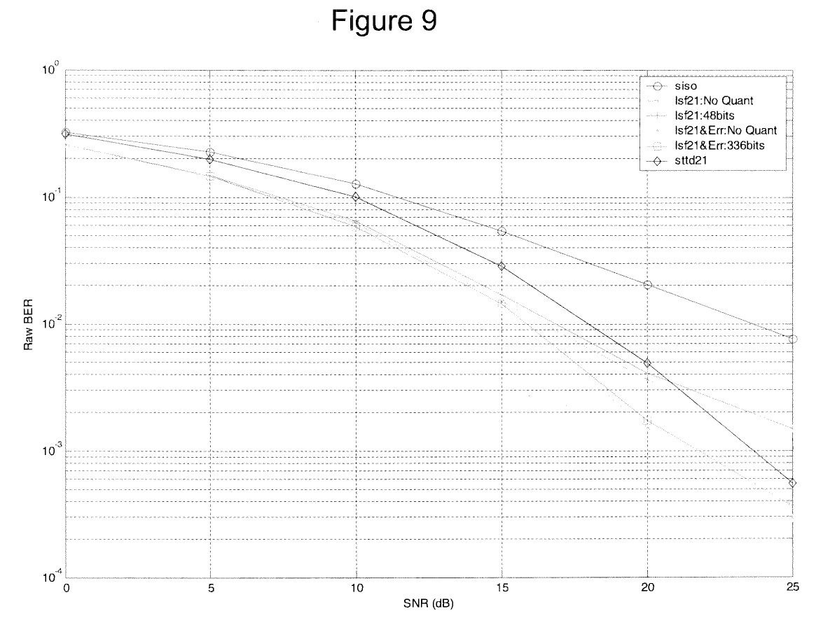

FIG. 9 shows the raw BER performance comparison of 2×1 LLSF beamforming schemes under 802.11n Channel B. First, compared to SISO curve, the LLSF BF shows a significant performance gain. The performance loss due to quantization seems to be less than 0.5 dB for both LLSF feedback parameters (lsf21 in FIG. 9) and LLSF parameters plus phase error feedback (lsf21&Err in FIG. 9). The performance of a 2×1 Alamouti open-loop system is also presented (sttd21 in FIG. 9). Under low SNR, both LLSF beamforming schemes seem to outperform the open-loop system by about 2 dB. However, at a high SNR of 20 dB and above, the LLSF BF scheme (lsf21) that feeds back only LLSF parameters starts to perform worse than the open-loop system. This observation seems to suggest that at low SNR, LLSF beamforming out performs the Alamouti open-loop system due to its strong array gain, but at high SNR phase errors associate with LLSF beamforming can be a limiting factor to obtain the steep diversity gain unlike in the Alamouti open-loop system. As shown in the FIG. 9, when marginal phase error deviations from the linear fitting are implemented (lsf21&Err), LLSF beamforming outperforms Alamouti open-loop system both at low and high SNR.

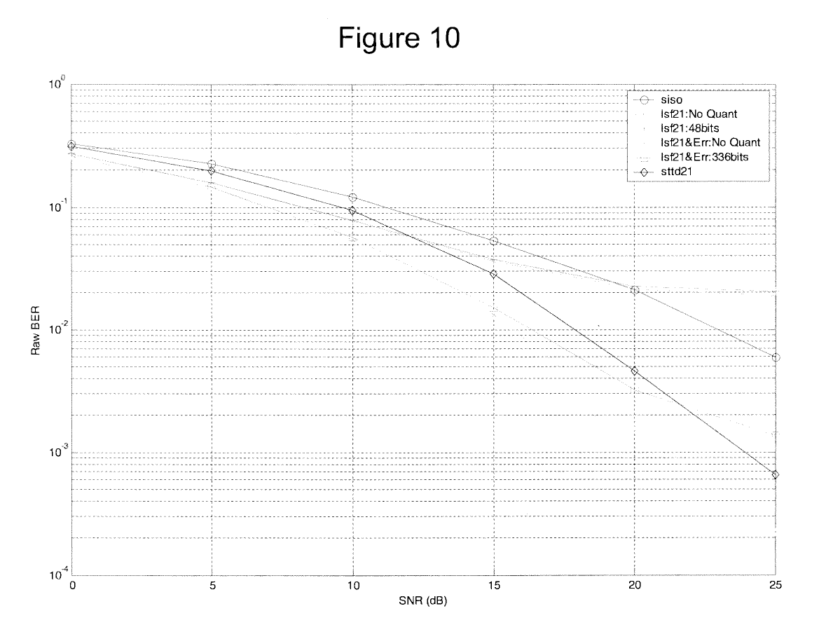

FIG. 10 shows the LLSF beamforming BER performance under 802.11n Channel D. Significant BER performance degradation is observed when LLSF parameters are only sent as feedback information (lsf21). One major reason for this degradation is due to the channel length. Since the channel length of Channel Model D is longer than the channel coherence length, this introduces inter-symbol interference (ISI) during the channel estimation process. Consequently, the channel estimation contains more significant errors compared to the true channel. The LLSF beamforming parameters to estimate the channel phases are less accurate, and this effect has been manifested by some performance flooring as shown in the FIG. 10. However, this problem can be eliminated by sending additional phase error information whose performance improvement is also shown (lsf21 &Err in FIG. 10).

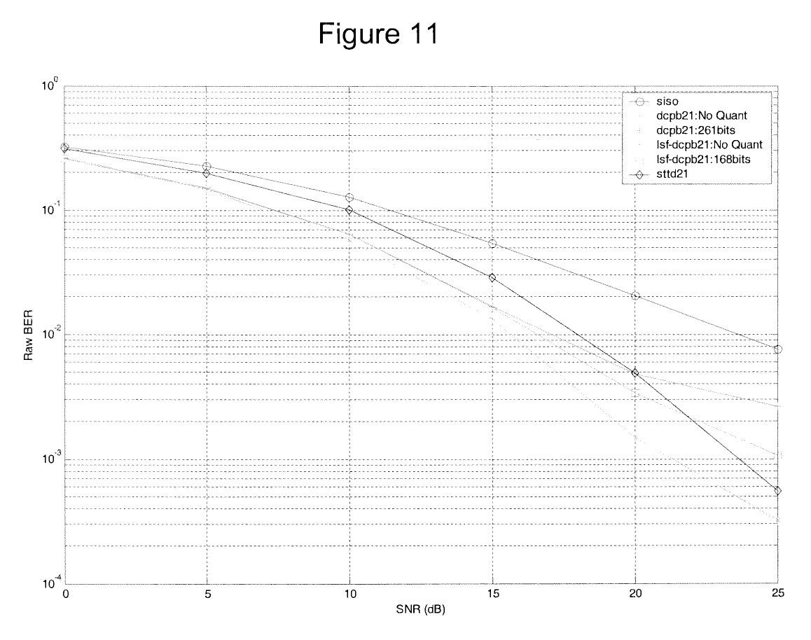

FIG. 11 shows the BER performance of DCP beamforming (dcpb21) and LSF-DCP beamforming (lsf-dcpb21) under 802.11n Channel B. The DCP beamforming performance at high SNR is rather disappointing since it seems to be more adversely affected by the quantization error. It is observed that, when beamforming weights are calculated at the transmitter as shown in the equation (18), more severe quantization error accumulates at the subcarriers of higher frequency thus limiting the overall performance. This indicates that DCP beamforming requires accurate feedback information. DCP-LLSF beamforming scheme seems to shows similar BER performance to LLSF beamforming (with LLSF parameter only feedback mode). There is still some quantization error accumulation although not as severe as in DCP beamforming. As in FIG. 9, neither beamforming scheme appears to provide the full diversity gain at high SNR compared to the open-loop system.

Overall, LLSF beamforming without marginal phase error feedback seems to require a least amount of feedback bits while still maintaining a desirable performance. DCP beamforming provides the simplest implementation, but its performance seems to be more adversely effected by quantization error accumulation/propogation. DCP-LLSF BF seems to provide some middle ground between LLSF and DCP in terms of its performance and the number of feedback information bits required.

In summary, based on the phase characteristic of the channel frequency response observed at the receiver, several MISO OFDM beamforming algorithms have been described, and their performance has been evaluated through computer simulations. A two transmitter antennas configuration simulation has shown that LLSF beamforming offers an excellent performance gain of at least 5 dB over SISO systems and 1 dB over an Alamouti open loop system at low SNR (below 20 dB) under 802.11n Channel B. It has also been shown that the loss of LLSF BF diversity gain at high SNR can be recovered if addition phase error information is transmitted to the transmitter with the nominal increase in feedback bits. Similarly, when significant errors exist in LLSF phase estimation due to inter-symbol interference or non-linearity, then sending back phase errors seems to improve the performance significantly even though more feedback bits are required. DCP beamforming offers the simplest implementation, but it suffers from quantization error accumulation which limits the full transmitter diversity gain at high SNR.

The beamforming schemes described herein are implemented in a single receive antenna system. The newly proposed BF scheme called Linear Least Square Fit (LLSF) BF utilizes the linear phase characteristic of a received signal. This linear phase characteristic is a feasible assumption since most receivers contain some type of linear phase analogue/digital filter implementation for signal extraction and recovery. This linear phase characteristic of the received OFDM symbol in the frequency domain can be unwrapped and parameterised by a linear least square fit function. Two parameters, one representing the slope and the other representing the initial bias, can be sent to the transmitter and used to regenerate the linear phase characteristic. The subsequent channel phase characteristic can then be used for beamforming. The computer simulations show that LLSF BF with quantized parameters yields at least 1 dB BER performance improvement over Alamouti open loop system under 802.11n Channel B environment. However, at high SNR (20 dB above), LLSF BF seems to yield less diversity gain compared to the open loop system. This issue has been resolved by sending marginal phase error information back to the transmitter.

The major advantage of the linear least square fit beamforming method is a smaller size of feedback information which is well suited for closed loop systems with limited feedback bandwidth. The scheme requires no heavy computation such as singular value decomposition or a matrix inversion operation. One disadvantage is the linear phase filter dependency. Accordingly, if a phase introduced by a receiver filter is not linear, this could lead to performance loss. However, degradations can be alleviated by sending additional bits to represent phase errors conveying phase deviation information from the linear least square fit phase estimation as described herein.

It is possible to implement embodiments of the invention in, for example, mobile base stations or access points to be used along with any single antenna wireless terminal product.

Embodiments provide a single receive antenna OFDM BF solution that exploits the phase characteristics of frequency domain OFDM symbols to overcome the potential performance degradation caused by limited feedback information. The OFDM BF arrangements are well-suited for a closed loop system with a limited feedback bandwidth without suffering from significant BF performance degradation. Three MISO OFDM BF schemes are proposed based on different exploitations of the phase characteristic of a channel frequency response. One major highlight of the proposed BF schemes is a linear least square fit BF method that utilizes the linear phase characteristics of the channel frequency response to parameterize the feedback information at the receiver and to help regenerate BF weights at the transmitter. The other proposed BF schemes utilize the subcarrier channel phase difference.

The required data processing functions may be provided by means of one or more data processor entities. All required processing may be provided in a mobile user equipment and a network element such as the base station transceiver/Node B or equivalent. Appropriately adapted computer program code product may be used for implementing the embodiments, when loaded to a computer or processor. The program code product for providing the operation may be stored on and provided by means of a carrier medium such as a carrier disc, card or tape. A possibility is to download the program code product via a data network. Implementation may be provided with appropriate software.

While this invention has been particularly shown and described with reference to preferred embodiments, it will be understood to those skilled in the art that various changes in form and detail may be made without departing from the scope of the invention as defined by the appended claims.

1. A method for beamforming comprising:
receiving a plurality of signals over a plurality of subcarriers, each subcarrier having a weight factor associated therewith;
analyzing the received signals in order to obtain a phase profile comprising phases of the subcarriers;
calculating a plurality of parameters representing the phase profile, the plurality of parameters being less in number than the number of subcarriers; and
sending the plurality of parameters to a transmitter for use in reconstruction of a representation of the phase profile.

2. The method according to claim 1, wherein the calculating comprises performing a linear least squares fit of the phase profile to obtain a first parameter representing an initial bias and a second parameter representing the slope of the linear least squares fit and the sending comprises sending the first and second parameters to the transmitter.

3. The method according to claim 1, wherein the calculating comprises calculating a phase difference for each subcarrier relative to a reference signal and the sending comprises sending parameters representing the phase differences to the transmitter.

4. The method according to claim 3, wherein the calculating comprises performing a linear least squares fit of the phase differences to obtain a first parameter representing an initial bias and a second parameter representing the slope of the linear least squares fit and the sending comprises sending the first and second parameters back to the transmitter.

5. The method according to claim 1, wherein the plurality of parameters representing the phase profile comprise values representing the phase profile.

6. The method according to claim 1, wherein each parameter is quantized into a number of bits.

7. The method according to claim 1, wherein the calculating comprises using a look-up table to generate indices matching the phase for each subcarrier with a closest value in a look-up table and the sending comprises sending the indices back to the transmitter.

8. The method according to claim 1, wherein the plurality of parameters representing the phase profile comprise one or more parameters representing phase error corrections.

9. The method according to claim 1, further comprising receiving a further plurality of signals with an adjusted the weight factor of each subcarrier, wherein the adjustment is based on the reconstructed representation of the phase profile.

10. The method according to claim 1, wherein the plurality of signals are received at a single receiver.

11. The method according to claim 1, wherein after the receiving step, each received signal is filtered to yield a substantially linear phase profile.

12. The method according to claim 1, further comprising:
transmitting the plurality of signals from the transmitter over the plurality of subcarriers;
sending the plurality of parameters back to the transmitter;
reconstructing a representation of the phase profile at the transmitter using the plurality of parameters;
adjusting the weight factor of each subcarrier using the reconstructed representation of the phase profile; and,
transmitting further signals using the adjusted weight factors.

13. A receiver configured to:
receive a plurality of signals over a plurality of subcarriers, each subcarrier having a weight factor associated therewith;
analyze the received signals to obtain a phase profile comprising phases of the subcarriers;
calculate a plurality of parameters representing the phase profile, the plurality of parameters being less in number than the number of subcarriers; and
send the plurality of parameters to a transmitter.

14. The receiver according to claim 13, comprising a processor configured to perform a linear least squares fit of the phase profile to obtain a first parameter representing an initial bias and a second parameter representing the slope of the linear least squares fit, wherein the receiver is configured to send the first and second parameters to the transmitter.

15. The receiver according to claim 13, comprising a processor configured to calculate a phase difference for each subcarrier relative to a reference signal, wherein the receiver is configured to send parameters representing the phase differences to the transmitter.

16. The receiver according to claim 15, wherein the processor is configured to perform a linear least squares fit of the phase differences to obtain a first parameter representing an initial bias and a second parameter representing the slope of the linear least squares fit, and the receiver is configured to send the first and second parameters to the transmitter.

17. The receiver according to claim 13, comprising a processor configured to use a look-up table to generate indices matching the phase for each subcarrier with a closest value in a look-up table, wherein the receiver is configured to send the indices to the transmitter.

18. The receiver according to claim 13, wherein the plurality of parameters representing the phase profile comprise one or more parameters representing phase error corrections.

19. The receiver according to claim 13, having only a single receiver antenna.

20. The receiver according to claim 13, comprising a filter arranged to filter each received signal to yield a substantially linear phase profile.

21. A mobile user equipment comprising the receiver of claim 13.

22. A method for beamforming comprising:
transmitting a plurality of signals over a plurality of subcarriers, each subcarrier having a weight factor associated therewith;
receiving a plurality of parameters from a receiver of the plurality of signals, the plurality of parameters representing a phase profile and being less in number than the number of subcarriers;
reconstructing a representation of the phase profile using the plurality of parameters;
adjusting the weight factor of each subcarrier using the reconstructed representation of the phase profile; and
transmitting further signals using the adjusted weight factors.

23. The method according to claim 22, wherein the reconstructing comprises reconstructing the linear least squares fit representing the phase profile and the adjusting comprises using the reconstructed least squares fit to adjust the weight factor of each subcarrier.

24. The method according to claim 22, wherein the reconstructing comprises reconstructing the linear least squares fit representing the phase differences, and the adjusting comprises using the reconstructed least squares fit being to adjust the weight factor of each subcarrier.

25. The method according to claim 22, wherein the reconstructing comprises using a look-up table to reconstructs a representation of the phase profile using the indices.

26. The method according to claim 22, comprising transmitting a signal by a plurality of antennas over a plurality of subcarriers, each antenna transmitting a signal over a plurality of subcarriers.

27. A transmitter configured to:
transmit a plurality of signals over a plurality of subcarriers, each subcarrier having a weight factor associated therewith,
receive, from a receiver of the signals, a plurality of parameters representing the phase profile of received signals, the plurality of parameters being less in number than the number of subcarriers;
reconstruct a representation of the phase profile using the plurality of parameters and adjust the weight factor of each subcarrier using the reconstructed representation of the phase profile; and
send further signals using the adjusted weight factors.

28. The transmitter according to claim 27, configured to
receive, from the receiver, a first parameter representing an initial bias and a second parameter representing the slope of a linear least squares fit of the phase profile of each signal,
reconstruct the linear least squares fit representing the phase profile of each signal using the first and second parameters, and
use the reconstructed least squares fit to adjust the weight factor of each subcarrier.

29. The transmitter according to claim 27, configured to
receive, from the receiver, parameters representing a phase difference for each subcarrier relative to a reference signal, and
reconstruct a representation of the phase profile using said parameters.

30. The transmitter according to claim 29, configured to
receive, from the receiver, a first parameter representing an initial bias and a second parameter representing the slope of a linear least squares fit of the phase differences,
reconstruct the linear least squares fit representing the phase differences, and
adjust the weight factor of each subcarrier using the reconstructed least squares fit.

31. The transmitter according to claim 27, configured to
receive, from the receiver, a plurality of indices matching the phase for each subcarrier with a closest value in a look-up table, and
use a look-up table to reconstruct a representation of the phase profile using the indices.

32. The transmitter according to claim 27, wherein the plurality of parameters representing the phase profile comprise one or more parameters representing phase error corrections and the processor is adapted to correct the adjusted weight factors using said one or more parameters.

33. A network entity of a telecommunications network comprising the transmitter of claim 27.

34. The network entity according to claim 33, wherein the network entity is a base station.

35. A communication system comprising a transmitter and a receiver, wherein
the receiver is configured to
receive a plurality of signals from the transmitter over a plurality of subcarriers, each subcarrier having a weight factor associated therewith;
analyze the received signals to obtain a phase profile comprising phases of the subcarriers,
calculate a plurality of parameters representing the phase profile, the plurality of parameters being less in number than the number of subcarriers, and
send the plurality of parameters to the transmitter, and the transmitter is configured to:
transmit the plurality of signals over the plurality of subcarriers, receive, from the receiver, the plurality of parameters;
reconstruct a representation of the phase profile using the plurality of parameters and adjust the weight factor of each subcarrier using the reconstructed representation of the phase profile; and
send further signals to the receiver using the adjusted weight factors.

36. A computer program embodied on a computer readable medium comprising program code means adapted to control a method comprising
receiving a plurality of signals over a plurality of subcarriers, each subcarrier having a weight factor associated therewith;
analyzing the received signals in order to obtain a phase profile comprising phases of the subcarriers;
calculating a plurality of parameters representing the phase profile, the plurality of parameters being less in number than the number of subcarriers; and
sending the plurality of parameters to a transmitter for use in reconstruction of a representation of the phase profile.

37. A computer program embodied on a computer readable medium comprising program code means adapted to control a method comprising:
transmitting a plurality of signals over a plurality of subcarriers, each subcarrier having a weight factor associated therewith;
receiving a plurality of parameters from a receiver of the plurality of signals, the plurality of parameters representing a phase profile and being less in number than the number of subcarriers;
reconstructing a representation of the phase profile using the plurality of parameters;
adjusting the weight factor of each subcarrier using the reconstructed representation of the phase profile; and
transmitting further signals using the adjusted weight factors.

38. A processor for a receiver, the processor being configured to:
analyse a plurality of signals received over a plurality of subcarriers, each subcarrier having a weight factor associated therewith to obtain a phase profile comprising phases of the subcarriers;
calculate a plurality of parameters representing the phase profile, the plurality of parameters being less in number than the number of subcarriers; and
instruct sending of the plurality of parameters to a transmitter.

39. A processor for a transmitter, the processor being configured to:
receive, from a receiver of signals, a plurality of parameters representing the phase profile of the signals transmitted over a plurality of subcarriers, each subcarrier having a weight factor associated therewith, the plurality of parameters being less in number than the number of subcarriers;
reconstruct a representation of the phase profile using the plurality of parameters and adjust the weight factor of each subcarrier using the reconstructed representation of the phase profile; and
instruct sending of further signals using the adjusted weight factors.
